(19) United States
(12) Patent Application Publication
(10) Pub. No.: US 2010/0032787 A1
(43) Pub. Date: Feb. 11, 2010

(54) Illumination intensity sensor and fabricating method thereof

(75) Inventor: Noriko Tomita, Gunma (JP)

Correspondence Address: RABIN & Berdo, PC, 1101 14TH STREET, NW, SUITE 500, WASHINGTON, DC, 20005, US

(73) Assignee: OKI SEMICONDUCTOR CO., LTD., Tokyo (JP)

(21) Appl. No.: 12/461,087

(22) Filed: Jul. 31, 2009

(30) Foreign Application Priority Data
Aug. 6, 2008 (JP) 2008-202618

(51) Int. Cl. H01L 31/101

(52) U.S. Cl. 257/461; 257/E31.054

(57) ABSTRACT

There is provided an illumination intensity sensor including a first photodiode; a second photodiode; an insulating film, the insulating film including a first insulating film portion above the first photodiode of a first film thickness and a second insulating film portion above the second photodiode of a second film thickness that is thicker than the first film thickness; first and second electrodes penetrating the first insulating film portion and electrically connected to the first and second conduction type diffusion region of the first photodiode, respectively; a second electrode penetrating the first insulating film portion and electrically connected to the second conduction type diffusion region of the first photodiode; and third and fourth electrodes penetrating the second insulating film portion and electrically connected to the first conduction type diffusion region of the second photodiode, respectively.

### CROSS-REFERENCE TO RELATED APPLICATION

This application claims priority under 35 USC 119 from Japanese Patent Application No. 2008-202618 filed on Aug. 6, 2008, the disclosure of which is incorporated by reference herein.

### BACKGROUND

1. Technical Field

The present invention relates to an illumination intensity sensor that determines the illumination intensity of light in a visible light region, and to a fabricating method thereof.

2. Related Art

Generally the peak sensitivity of spectral sensitivity characteristics of illumination intensity sensors for controlling illumination and controlling brightness of back lights etc. is now from about 500 nm to about 600 nm, which is becoming closer to the peak sensitivity of human spectral sensitivity that is at 555 nm.

However, sometimes the problem arises that even though there is the same illumination intensity, the output current differs in cases where the light source is fluorescent lighting and cases where the light source is sunlight. This is caused by factors such as differences in the emission spectra depending on the light source, and illumination intensity sensors having sensitivity to infrared light (wavelengths of 700 nm and above) and to ultraviolet light (wavelengths of 400 nm and below) to which the human eye has no sensitivity. In other words, in order to match the sensitivity of an illumination intensity sensor to human spectral sensitivity characteristics, not only the peak wavelengths of the spectral sensitivity characteristics need to be matched, but the spectral sensitivity characteristics from the peak sensitivity toward the long wavelength side and toward the short wavelength side, respectively, also need to be matched to human spectral sensitivity characteristics.

Generally, when trying to obtain such desired spectral sensitivity characteristics, optical filters are formed over photodiodes, so as to obtain spectral sensitivity characteristics that are close to those of human spectral sensitivity.

When such optical filters are used, in order to avoid the problem of an increase in manufacturing cost, existing light receiving elements form a photodiode by forming a P well layer on the front surface side of an N type semiconductor substrate, and forming an N-type diffusion layer in the surface layer of this P well layer. Three photodiodes of such a configuration are then disposed alongside each other, filter films with different film thicknesses are formed from poly-silicon on each of the respective photodiodes using photolithographic etching, and an infrared ray cut filter is formed on the filter film. Utilizing the transmission properties of light in different wavelength regions due to the film thicknesses of the poly silicon, three signals of brightness to different wavelength regions are extracted from the photodiodes, and by arithmetic processing on these outputs, a color signal is detected with separated blue region, green region and red region (see, for example, Japanese Patent Application Laid-Open (JP-A) No. 2005-175430 (paragraphs [0030], [0041] to [0058], and FIG. 2).

However, in the existing technology as described above, since electrically conductive poly silicon is used for the filter film, the electrodes for extracting the photoelectric current from the N-type diffusion layer etc. are lead out from a region where there is no filter film present in the vertical direction from the surface of the page in FIG. 3 of JP-A No. 2005-175430, with this requiring space and leading to the problem that the light receiving element becomes bulky in size.

### SUMMARY

The present invention is one that solves the above problems, and provides a method of achieving compactness in a light receiving element of an illumination intensity sensor.

In order to solve the above problems the present invention provides an illumination intensity sensor including:

a first photodiode including
a semiconductor substrate diffused with a first conduction type impurity,
a well region, formed on a front surface of the semiconductor substrate with a dispersed second conduction type impurity of opposite conductive type to that of the first conduction type impurity, and, disposed alongside each other on the front side in the well region,
a first conduction type diffusion region formed by diffusion of the first conduction type impurity and
a second conduction type diffusion region formed by diffusion of the second conduction type impurity;

a second photodiode disposed alongside the first photodiode and with the same configuration as the first photodiode;

an insulating film with transparency and insulating properties formed on the front surface of the first photodiode and on the front surface of the second photodiode, the insulating film including a first insulating film portion above the first photodiode of a first film thickness and a second insulating film portion above the second photodiode of a second film thickness that is thicker than the first film thickness;

a first electrode penetrating the first insulating film portion and electrically connected to the first conduction type diffusion region of the first photodiode;

a second electrode penetrating the first insulating film portion and electrically connected to the second conduction type diffusion region of the first photodiode;

a third electrode penetrating the second insulating film portion and electrically connected to the first conduction type diffusion region of the second photodiode: and

a fourth electrode penetrating the second insulating film portion and electrically connected to the second conduction type diffusion region of the second photodiode.

Accordingly, even though the first and second photodiodes are of the same configuration, the present invention can make different characteristics for the spectral sensitivity characteristics of photoelectric current extracted for the first photodiode and the second photodiode, utilizing the change in transmissivity to light due to discrepancies in the film thickness of the first film thickness of the first insulating film portion and the second film thickness of the second insulating film portion, and can obtain an illumination intensity sensor with a peak sensitivity in the visible light region by arithmetic processing on the extracted photoelectric currents. In addition, utilizing the insulating properties of the first and second insulating film portions that function as filters, it becomes possible to form the first to fourth electrodes, connecting the respective first conduction type diffusion regions and the respective second conduction type diffusion regions of the first photodiode and the second photodiode, directly on the first and second insulating film portions of the first and second photodiodes, obtaining the effect that a more compact illumination intensity sensor can be achieved by reducing the surface area of the light receiving element in plan view.

Further, in another aspect of the present invention provides an illumination intensity sensor fabricating method including:

preparing a semiconductor substrate diffused with a first conduction type impurity;

forming well regions of the first photodiode and the second photodiode respectively by diffusing a second conduction type impurity that is different from the first conduction type impurity in forming regions for the well regions on the front surface of the semiconductor substrate;

forming first conduction type diffusion regions by diffusing the first conduction type impurity in respective forming regions for first conduction type diffusion regions of the first photodiode and the second photodiode on the front surface side in the respective well regions;

forming a second conduction type diffusion region by diffusing the second conduction type impurity in respective forming regions for second conduction type diffusion regions that are disposed alongside the first conduction type diffusion regions of the first photodiode and the second photodiode at the front surface side in the respective well regions;

forming an insulating film of a second film thickness from an insulating material that has light transmitting properties and insulating properties on the front surface of the first photodiode and the second photodiode;

etching the insulating film above the first photodiode so as to form a first insulating film portion of a first film thickness that is thinner than the second film thickness and forming a second insulating film portion of a second film thickness above the second photodiode;

forming first and second electrodes penetrating the first insulating film portion respectively electrically connected to the first conduction type diffusion region and second conduction type diffusion region of the first photodiode, and forming third and fourth electrodes penetrating the second insulating film portion respectively electrically connected to the first conduction type diffusion region and second conduction type diffusion region of the second photodiode.

Here, the first film thickness may be a thickness in the range of from 300 nm to 350 nm, and the second film thickness may be in the range of from 400 nm to 450 nm.

### BRIEF DESCRIPTION OF THE DRAWINGS

Exemplary embodiments of the present invention will be described in detail based on the following figures, wherein:

FIG. 1 is an explanatory diagram showing a cross-section of a light receiving element of an exemplary embodiment;

FIG. 2 is an explanatory diagram showing a top face of a light receiving element of an exemplary embodiment;

FIG. 3 is a circuit diagram showing an equivalent circuit of a computational circuit of an exemplary embodiment;

FIG. 4A to 4E are explanatory diagrams showing a fabricating method of a light receiving element of an exemplary embodiment;

FIG. 5 is a graph showing wavelength dependency of photoelectric current of a photodiode formed with an insulating film of film thickness 300 nm to 350 nm in an exemplary embodiment;

FIG. 6 is a graph showing wavelength dependency of photoelectric current of a photodiode formed with an insulating film of film thickness 400 nm to 450 nm in an exemplary embodiment;

FIG. 7 is an explanatory diagram showing an operation mode of a light receiving element of an exemplary embodiment; and

FIG. 8 is a graph showing spectral sensitivity characteristics of an illumination intensity sensor of an exemplary embodiment.

### DETAILED DESCRIPTION

Explanation will now be given of an exemplary embodiment of an illumination intensity sensor according to the present invention and a fabricating method thereof, with reference to the drawings.

### Exemplary Embodiment

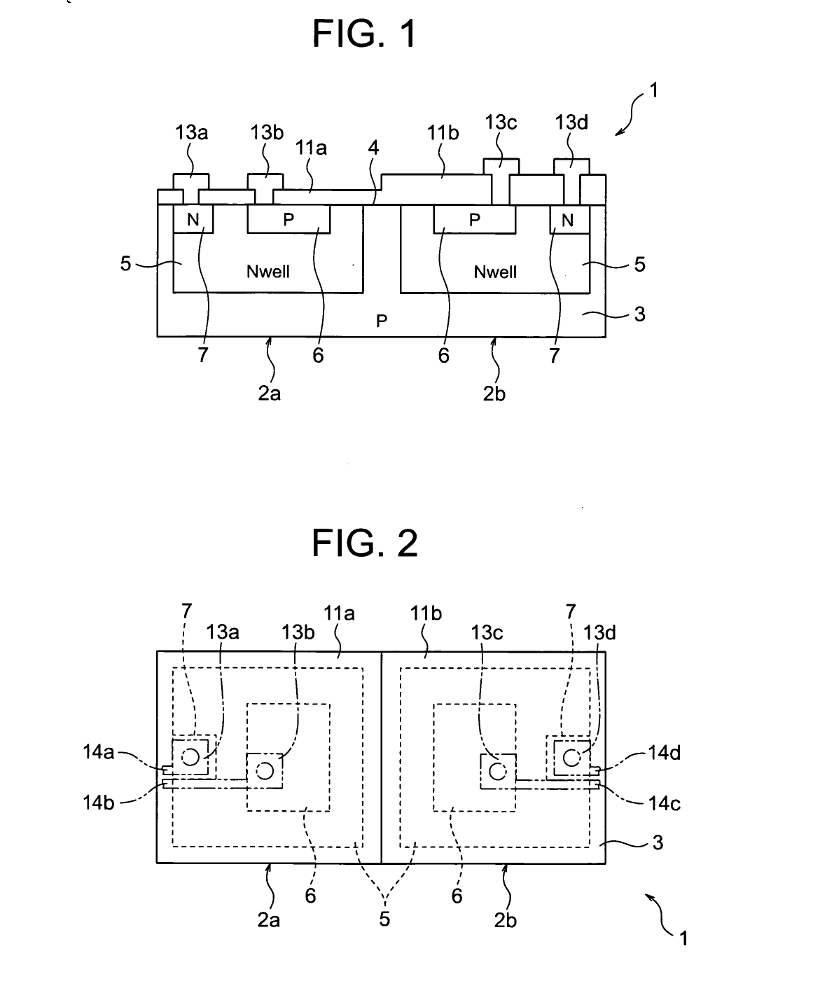

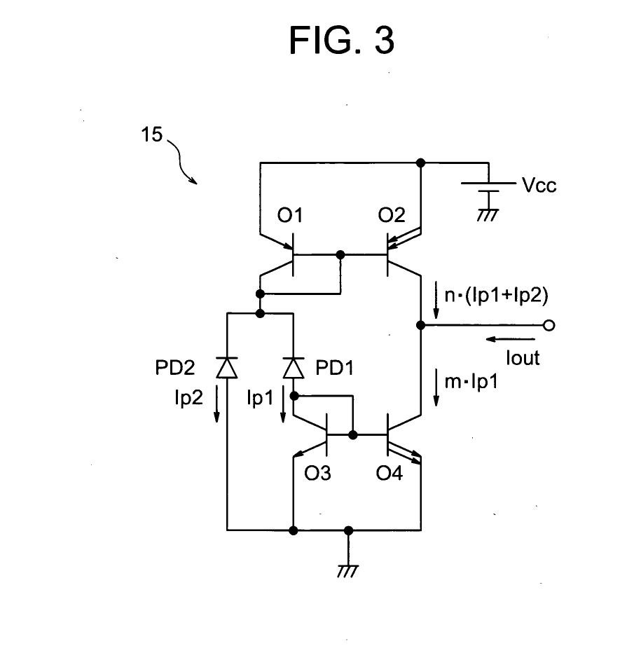

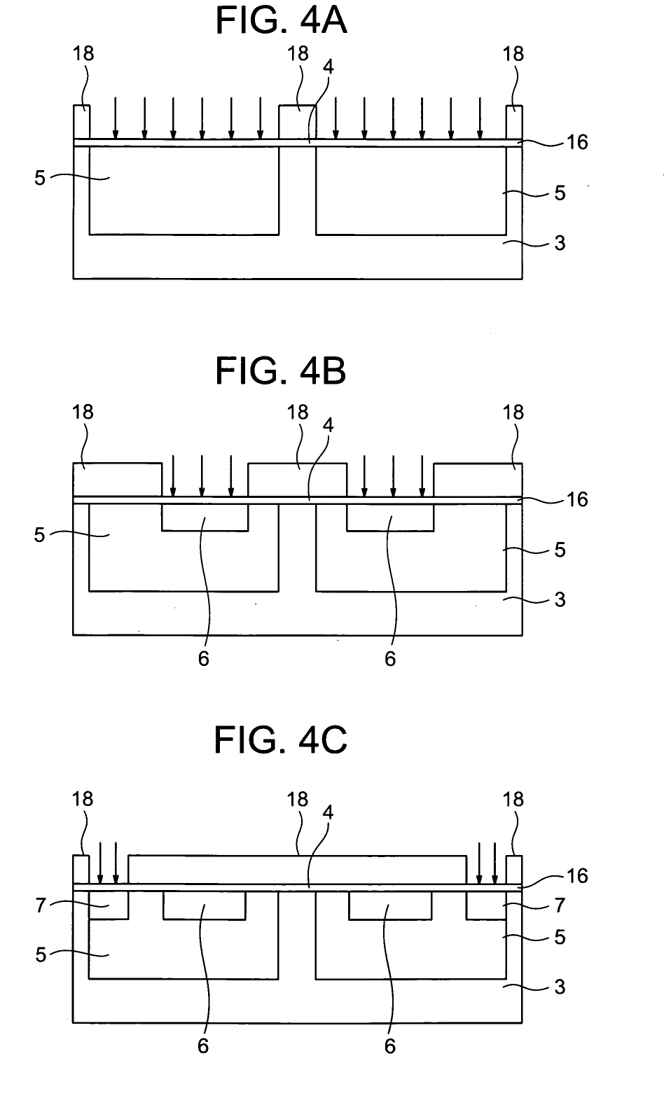

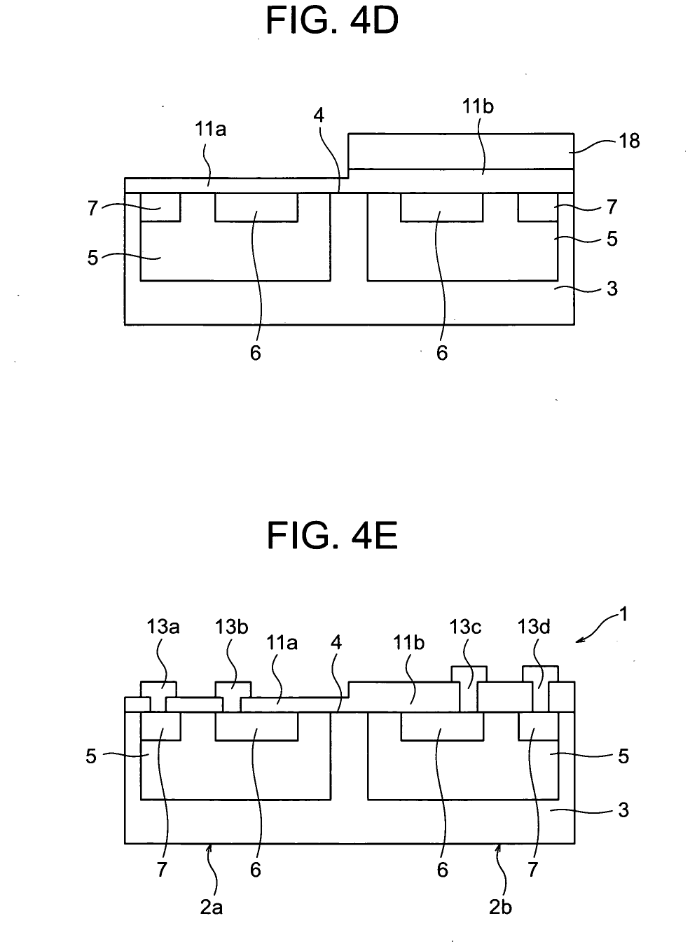

FIG. 1 is an explanatory diagram showing a cross-section of a light receiving element of an exemplary embodiment, FIG. 2 is an explanatory diagram showing a top face of a light receiving element of an exemplary embodiment, FIG. 3 is a circuit diagram showing an equivalent circuit of a computational circuit of an exemplary embodiment; and FIG. 4A to 4E are explanatory diagrams showing a fabricating method of a light receiving element of an exemplary embodiment.

It should be noted that FIG. 2 is a diagram of the top face shown in a state in which electrodes and wiring lines have been removed.

The present inventor has noticed, from recent tests carried out in illumination intensity sensor development, that the wavelength regions of light transmitted through an insulating film, such as an intermediate insulating film formed from transparent silicon oxide that has light transmitting properties due to being transparent or semi-transparent, depend on the thickness of the insulating film.

In order to prove this effect, the present inventor produced plural photodiodes formed with insulating films of different film thicknesses, irradiated light thereon for each wavelength of a wavelength distribution of 300 nm to 1100 nm, and investigated the wavelength dependency of photoelectric current detected from the photodiodes.

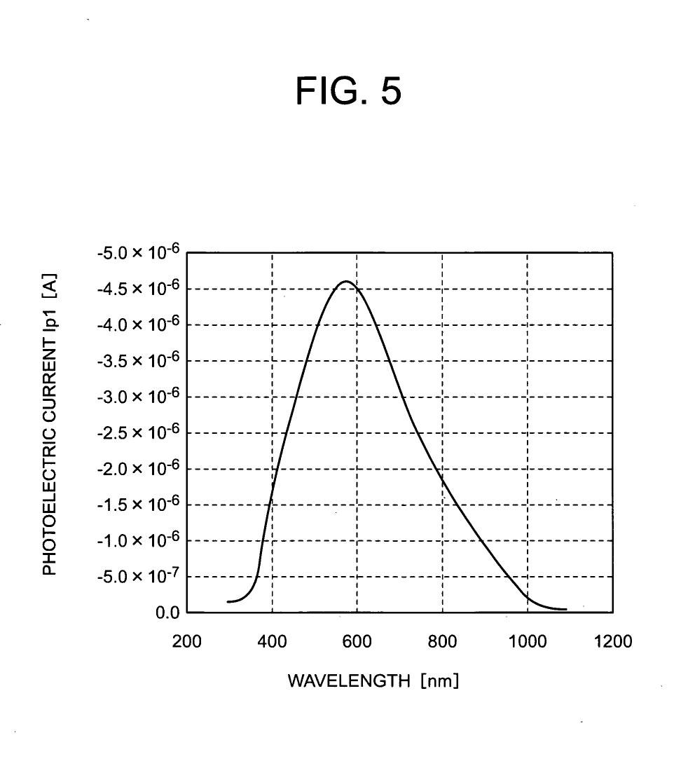

FIG. 5 shows the wavelength dependency of photoelectric current of a photodiode formed with a film thickness of 300 nm to 350 nm, with the photoelectric current Ip1 thereof having spectral sensitivity characteristics with a peak sensitivity in the vicinity of wavelengths from 555 nm to 580 nm.

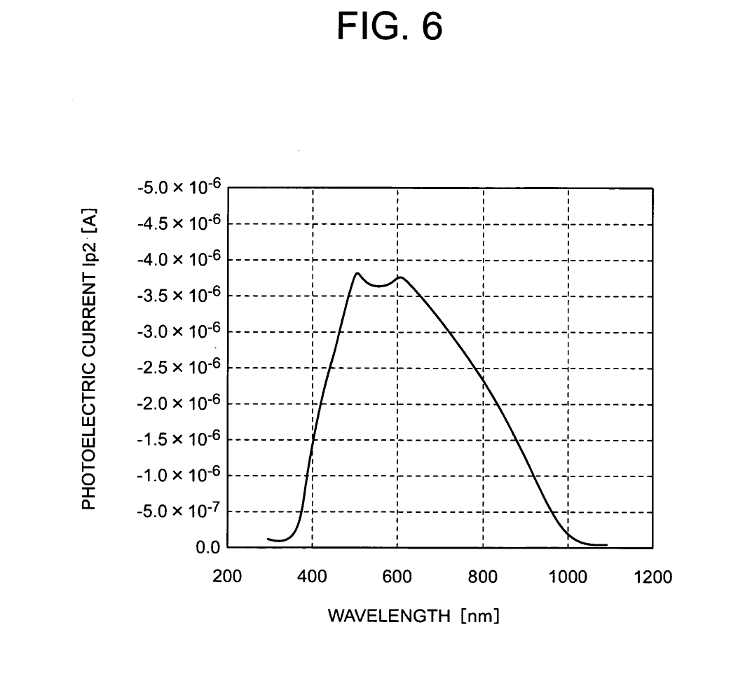

FIG. 6 shows the wavelength dependency of photoelectric current of a photodiode formed with a film thickness of 400 nm to 450 nm, with the photoelectric current Ip2 thereof having spectral sensitivity characteristics with a peak sensitivity in the vicinity of wavelengths from 500 nm to 600 nm, and having high spectral sensitivity in the infrared light region of 700 nm and above.

Utilizing the spectral sensitivity characteristics of these two photodiodes formed with insulating films of differing film thicknesses, it is possible to obtain an illumination intensity sensor having a peak sensitivity in the visible light region by arithmetic processing on the respective photoelectric currents Ip1, Ip2 to cancel out the spectral sensitivity in the infrared region. It can be seen that it is possible to achieve a more compact illumination intensity sensor by forming an electrode on the insulating film that is functioning as a filter.

Explanation will now be given of an illumination intensity sensor of a present exemplary embodiment that has been based on the above discovery.

In FIG. 1 and FIG. 2, a light receiving element 1 is equipped with a first photodiode 2a and a second photodiode 2b that are the same configurations as each other disposed alongside each other.

It should be noted that where there is no requirement to differentiate between the first and second photodiodes 2a, 2b then reference will simply be made to photodiode 2.

A semiconductor substrate 3 is formed from a silicon (Si) substrate, diffused with a P-type impurity, such as boron (B) or boron difluoride (BF₂), serving as a first conduction type impurity.

The semiconductor substrate 3 of the present exemplary embodiment is formed by diffusing boron as the P-type impurity at a concentration of about 1×10¹⁵/cm³.

A well region 5, serving as an N well region, is formed by diffusing an N-type impurity, such as phosphorous (P) or arsenic (As), serving as a second conduction type impurity different from the first conduction type impurity, into the front surface 4 of the semiconductor substrate 3.

The well region 5 in the present exemplary embodiment is formed by diffusing phosphorous, serving as the N-type impurity at a concentration of about 1×10¹⁷/cm³.

A P-type diffusion region 6, serving as a first conduction type diffusion region, is formed by diffusing a P-type impurity at a relatively high concentration into the front surface 4 in the N well region 5. The P-type diffusion region 6 functions as a light receiving region for light irradiated from the front surface 4.

The P-type diffusion region 6 in the present exemplary embodiment is formed by diffusing boron difluoride as the P-type impurity at a concentration of 1×10²⁰/cm³ or greater. An N-type dispersed region 7, serving as a second conduction type diffusion region, is formed by diffusing an N-type impurity at a relatively high concentration into the front surface 4 in the N well region 5. The N-type dispersed region 7 is disposed in the N well region 5 alongside the P-type diffusion region 6 with a separation therebetween, in order to make a second electrode 13a and a fourth electrode 13d, described later, be in ohmic contact with their respective N well regions 5.

The N-type dispersed region 7 of the present exemplary embodiment is formed by diffusing phosphorous as the N-type impurity at a concentration of 1×10²⁰/cm³ or greater. The photodiodes 2 of the present exemplary embodiment are configured as described above, by the N well region 5 formed in the front surface 4 of the semiconductor substrate 3, and by the P-type diffusion region 6 and the N-type dispersed region 7 disposed alongside each other in the N well region 5. The photodiodes 2 have a first PN junction formed by the P-type diffusion region 6 and the N well region 5, and a second PN junction formed by the P-type semiconductor substrate 3 and the N well region 5.

In the present exemplary embodiment, the first PN junction is provided at a depth of about 700 nm from the front surface 4 of the semiconductor substrate 3.

An insulating film 11 is an insulating film formed from silicon oxide (SiO₂) and has electrical insulating and light transmitting properties. The insulating film 11 is configured with a first insulating film portion 11a formed with a first film thickness above the front surface 4 of the first photodiode 2a, and a second insulating film portion 11b formed with a second film thickness above the front surface 4 of the second photodiode 2b, the second film thickness being thicker than the first film thickness. The first and second insulating film portions 11a and 11b function as light filters for the respective first and second photodiodes 2a and 2b, and also function as protective films for the light receiving element 1.

In the present exemplary embodiment the first film thickness is set as a thickness in the range of 300 nm to 350 nm, and the second film thickness is set as a thickness in the range of 400 nm to 450 nm.

The second electrode 13a, a first electrode 13b, a third electrode 13c, and the fourth electrode 13d are formed of an electrically-conductive material such as aluminum (Al) or the like, with the second electrode 13a penetrating the first insulating film portion 11a and electrically connecting to the N-type dispersed region 7 of the first photodiode 2a, the first electrode 13b penetrating the first insulating film portion 11a and electrically connecting to the P-type diffusion region 6 of the first photodiode 2a, the third electrode 13c penetrating the second insulating film portion 11b and electrically connecting with the P-type diffusion region 6 of the second photodiode 2b, the fourth electrode 13d penetrating the second insulating film portion 11b and electrically connecting with the N-type dispersed region 7 of the second photodiode 2b.

FIG. 2 shows wiring lines 14a to 14d as double-dash intermittent lines, the wiring lines 14a to 14d being formed from the same electrically-conductive material as that of the first to the fourth electrodes 13a to 13d. So as to be careful not to block light irradiated onto the P-type diffusion region 6, the wiring lines 14b and 14a extend from the first and second electrodes 13b and 13a in the opposite direction to that of the second photodiode 2b disposed alongside, and the wiring lines 14c and 14d extend from the third and fourth electrodes 13c and 13d in the opposite direction to that of the first photodiode 2a disposed alongside, with the wiring lines 14a to 14d connecting to specific locations of a arithmetic circuit 15.

In the present exemplary embodiment, transistors O1 to O4 and a wiring pattern etc. configuring the arithmetic circuit 15 shown in FIG. 3, are formed on the semiconductor substrate 3, together with the above described light receiving element 1.

The arithmetic circuit 15 has functionality for arithmetic processing on the photoelectric current generated from the first photodiode 2a (shown in FIG. 3 as PD 1) and the second photodiode 2b (PD 2) by light irradiation, and for outputting an output current (I out) having a peak at a specific wavelength (about 570 nm in the present exemplary embodiment). The arrow shown in FIG. 3 denotes the direction of current flow.

In the illumination intensity sensor of the present exemplary embodiment is configured from the arithmetic circuit 15, and the light receiving element 1 equipped with the first and second photodiodes 2a and 2b provided with the first and second insulating film portions 11a and 11b of different film thicknesses.

In FIG. 4A to 4D, a protective layer 16 of an insulating layer of about 10 nm film thickness is formed from silicon oxide or the like on the front surface 4 of the semiconductor substrate 3, for the purpose of reducing damage to the front surface 4 of the semiconductor substrate 3 during ion implantation processes.

A resist mask 18 is a mask pattern formed using photolithography, by applying a positive-working or negative-working resist onto the front surface 4 of the semiconductor substrate 3, using a spin coating method or the like, light exposure thereof, and developing. In the present exemplary embodiment the resist mask 18 functions as a mask in etching processes and ion implantation processes etc.

Explanation will now be given of a fabricating method of the light receiving element of the present exemplary embodiment, according to the processes shown in FIG. 4A to FIG. 4E.

In FIG. 4A a semiconductor substrate 3 is prepared, and, using a thermal oxidation method, the protective layer 16 of about 10 nm film thickness is formed from silicon oxide by thermal oxidation of the front surface 4 of the semiconductor substrate 3.

Then, using photolithography, a resist mask 18 is formed on the protective layer 16, with the forming regions of the protective layer 16 of the respective N well regions 5 of the first and second photodiodes 2a and 2b exposed. N-type impurity (phosphorous in the present exemplary embodiment) ions are then implanted with an implantation energy of 2000 to 2400 KeV using this resist mask 18 as a mask, forming the N well regions 5 below the protective layer 16 on the front surface 4 of the semiconductor substrate 3 at an impurity concentration of 1×10¹⁷/cm³.

In FIG. 4B, the resist mask 18 formed in FIG. 4A is removed, and a resist mask 18 is formed on the protective layer 16 with the protective layer 16 of the respective P-type diffusion regions 6 of the first and second photodiodes 2a and 2b exposed. P-type impurity (boron difluoride in the present exemplary embodiment) ions are then implanted with an implantation energy of 40 to 70 KeV using this resist mask 18 as a mask, forming the P-type diffusion regions 6 at the front surface 4 of the N well region 5 below the protective layer 16 at an impurity concentration of 1×10²⁰/cm³ to a depth of about 700 nm from the front surface 4.

In FIG. 4C, the resist mask 18 formed in FIG. 4B is removed, and a resist mask 18 is formed by photolithography on the protective layer 16 with the protective layer 16 of the forming regions for the respective N-type dispersed regions 7 of the first and second photodiodes 2a and 2b exposed. N-type impurity (phosphorous in the present exemplary embodiment) ions are then implanted with an implantation energy of 60 KeV using this resist mask 18 as a mask, forming the N-type dispersed regions 7 disposed alongside the P-type diffusion regions 6 at the front surface 4 of the N well region 5 below the protective layer 16 at an impurity concentration of 1×10²⁰/cm³.

In FIG. 4D, the resist mask 18 formed in FIG. 4C is removed, and after removing the protective layer 16 by wet etching, silicon oxide is deposited at the second film thickness of 400 nm to 450 nm by a CVD (Chemical Vapor Deposition) method, forming the insulating film 11 on the front surface 4 of the semiconductor substrate 3.

A resist mask 18 is then formed by photolithography on the insulating film 11, with the insulating film 11 of the forming region for the first insulating film portion 11a exposed, namely with the forming region for the second insulating film portion 11b covered. The insulating film 11 is then etched using anisotropic etching with this resist mask 18 as a mask, forming the first insulating film portion 11a at the first film thickness of 300 nm to 350 nm on the first photodiode 2a, and forming the second insulating film portion 11b at the second film thickness of 400 nm to 450 nm on the second photodiode 2b.

In FIG. 4E, the resist mask 18 formed in FIG. 4D is then removed, and a resist mask 18 (not illustrated) is formed using photolithography on the first and second insulating film portions 11a and 11b, the resist mask 18 having opening portions exposing the first insulating film portion 11a at the forming region of the contact holes with the second electrode 13a of the N-type dispersed region 7 and the first electrode 13b of the P-type diffusion region 6 of the first photodiode 2a, and exposing the second insulating film portion 11b at the forming regions of the contact holes with the third electrode 13c of the P-type diffusion region 6 and the fourth electrode 13d of the N-type dispersed region 7 of the second photodiode 2b. The first and second insulating film portions 11a and 11b are then etched by anisotropic etching using this resist mask 18 as a mask, forming contact holes down to the N-type dispersed region 7 and the P-type diffusion region 6 of the first photodiode 2a, and to the P-type diffusion region 6 and the N-type dispersed region 7 of the second photodiode 2b, respectively.

This resist mask 18 is then removed, and electrically-conductive material formed from aluminum is deposited using a sputtering method in each of the contact holes, and on the first and second insulating film portions 11a and 11b, filling the inside of each of the contact holes with electrically-conductive material and forming an electrically-conductive material film on the first and second insulating film portions 11a and 11b.

Next, a resist mask 18 (not illustrated) is formed by photolithography on the electrically-conductive material film, covering the electrically-conductive material film of the forming regions of the first to the fourth electrodes 13a to 13d, and the wiring lines 14a to 14d. The electrically-conductive material film is then etched by anisotropic etching using this resist mask 18 as a mask, the first and second insulating film portions 11a and 11b exposed, and the first to the fourth electrodes 13a to 13d, and the wiring lines 14a to 14d are formed, electrically connecting to the respective P-type diffusion regions 6 and the respective N-type dispersed regions 7 of the first and second photodiodes 2a and 2b.

It should be noted that the first and second insulating film portions 11a and 11b are formed with different film thicknesses, however in the present exemplary embodiment the difference in film thickness between the first film thickness of the first insulating film portion 11a and the second film thickness of the second insulating film portion 11b is of the order of about 50 nm to 150 nm. Therefore, the first to the fourth electrodes 13a to 13d can all be formed at the same time on the first and second insulating film portions 11a and 11b of different film thicknesses, without needing to consider the focal point during exposure of the resist mask 18, or needing to consider excessive etching when performing etching.

The light receiving element 1 of the present exemplary embodiment is formed in this manner.

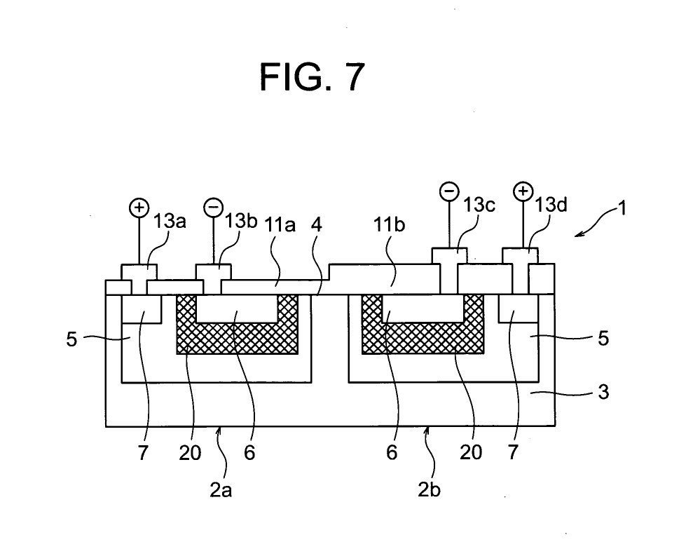

To measure illumination intensity with the above light receiving element 1, the wiring line 14a connected to the second electrode 13a of the first photodiode 2a, and the wiring line 14d connected to the fourth electrode 13d of the second photodiode 2b, are connected to the positive terminal of a biasing source, and the wiring line 14b connected to the first electrode 13b of the first photodiode 2a and the wiring line 14c connected to the third electrode 13c of the second photodiode 2b are connected to the negative terminal of the biasing source, and a reverse bias voltage of the order of about 1V is applied thereto. When this is performed, a depleted layer 20 is formed in the vicinity of the first PN junctions formed by the respective N well regions 5 and P-type diffusion regions 6 of the first and second photodiodes 2a and 2b, as shown by cross-hatching in FIG. 7.

When light including wavelength components of 300 nm to 1100 nm, which is equivalent to light from sunlight or fluorescent lights, is irradiated on the light receiving element 1 in this state, electron-hole pairs are generated in the depleted layer 20 regions of each of the first and second photodiodes 2a and 2b. The electrons are accelerated toward N-type dispersed region 7 or the N well region 5 by the internally generated electrical field, the holes accelerate towards the P-type diffusion region 6 or the P-type semiconductor substrate 3, and a photoelectric current is detected from the second electrode 13a and the fourth electrode 13d.

In this case the wavelength dependency of the photoelectric current Ip1 detected from the first photodiode 2a formed with the first insulating film portion 11a of the first film thickness of 300 nm to 350 nm has, as shown in FIG. 5, spectral sensitivity characteristics with a peak sensitivity in the vicinity of 555 nm to 580 nm.

The photoelectric current Ip2 detected from the second photodiode 2b formed with the second insulating film portion 11b of the second film thickness of 400 nm to 450 nm has spectral sensitivity characteristics with a peak sensitivity in the vicinity of 500 nm to 600 nm, and with high spectral sensitivity in the infrared light region of 700 nm and above.

When light is irradiated, even though the first and second photodiodes 2a and 2b have the same configuration, the wavelength regions of light arriving on the first and second photodiodes 2a and 2b are different, because of the disparity of transmittance to light due to the difference between the first film thickness of the first insulating film portion 11a and the second film thickness of the second insulating film portion 11b formed respectively thereon, functioning as filters that selectively transmit light.

Arithmetic Processing

I out=Ip1−K×Ip2 (1)

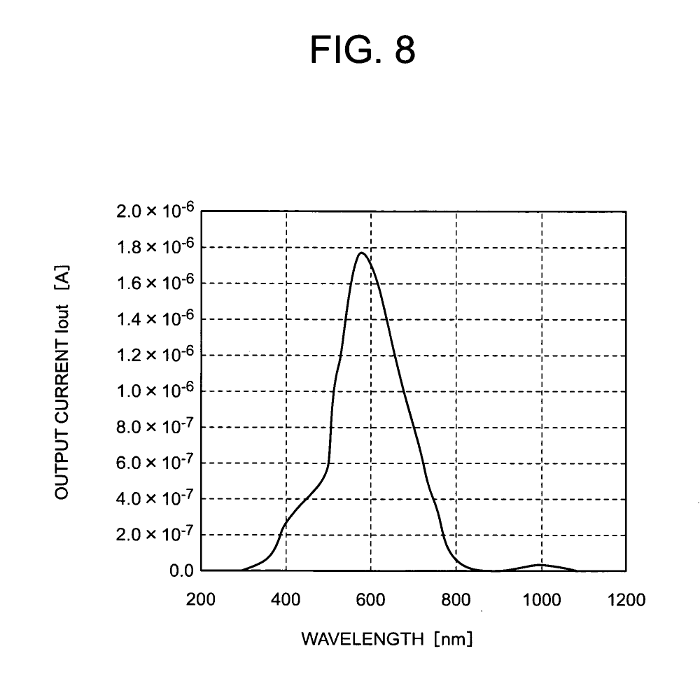

is performed by the arithmetic circuit 15 on the photoelectric currents Ip1, Ip2 detected in the first and second photodiodes 2a and 2b, and spectral sensitivity characteristics are obtained with a peak sensitivity of wavelength about 570 nm, as shown in FIG. 8, forming an illumination intensity sensor for measuring the illumination intensity of light in the visible light region having a peak sensitivity (wavelength about 570 nm) close to that of the peak sensitivity of human spectral sensitivity characteristics (wavelength 555 nm).

It should be noted that in Equation (1), K is a constant set in order that the spectral sensitivity to the infrared light region of the photoelectric current Ip1 is cancelled out by the spectral sensitivity of the photoelectric current Ip2.

As described above, in the present exemplary embodiment, the first and second photodiodes 2a and 2b, each of the same configuration, are disposed alongside each other on the same semiconductor substrate 3, and the first and second insulating film portions 11a and 11b are formed respectively thereon of different film thicknesses. Consequently, even though the first and second photodiodes 2a and 2b are of the same configuration as each other, by utilizing the property of the change in transmissivity to transmitted light, due to the discrepancy in the film thicknesses of the first and second insulating film portions 11a and 11b, the spectral sensitivity characteristics of the photoelectric currents Ip1, Ip2 detected from the first and second photodiodes 2a and 2b, formed with the first and second insulating film portions 11a and 11b, can be made to have different characteristics from each other, and by arithmetic processing an illumination intensity sensor can be realized having a peak sensitivity in the visible light region.

The first film thickness of the first insulating film portion 11a was made a thickness in the range of 300 nm to 350 nm, and the second film thickness of the second insulating film portion 11b was made a thickness in the range of 400 nm to 450 nm. Therefore, the photoelectric current Ip1 detected from the first photodiode 2a can be made to have spectral sensitivity characteristics with a peak sensitivity in the vicinity of 555 nm to 580 nm, and the photoelectric current Ip2 detected in the second photodiode 2b can be made to have spectral sensitivity characteristics with a peak sensitivity in the vicinity of 500 nm to 600 nm and with high spectral sensitivity in the infrared light region of 700 mm and greater. By arithmetic processing thereon, cancelling out the spectral sensitivity in the infrared light region, an illumination intensity sensor can be obtained for detecting illumination intensity to light in the visible light region, having a peak sensitivity near to the peak sensitivity of human spectral sensitivity characteristics.

In addition, the first and second insulating film portions 11a and 11b, functioning as filters in the present exemplary embodiment, are formed from insulating materials. It therefore becomes possible to form the first to the fourth electrodes 13a to 13d and the wiring lines 14a to 14d, for connecting the P-type diffusion regions 6 and the N-type dispersed regions 7 of the first and second photodiodes 2a and 2b, directly on the first and second insulating film portions 11a and 11b that are directly formed on the first and second photodiodes 2a and 2b, so that a reduction in the surface area of the light receiving element 1 when seen in plan view from above, thinning of the thickness of the light receiving element 1, and more compactness of the illumination intensity sensor can be achieved.

As explained above, the present exemplary embodiment is a P-type-impurity-diffused semiconductor substrate formed with a first photodiode and a second photodiode having the same configuration as each other, each having a N well region formed on the front surface side of the semiconductor substrate with a P-type diffusion region and an N well region disposed alongside each other in the respective N well regions. An insulating film with transparency and insulating properties is formed on the front surface of the first photodiode and on the front surface of the second photodiode, the insulating film including a first insulating film portion of a first film thickness and a second insulating film portion of a second film thickness that is thicker than the first film thickness. First and second electrodes are provided on the first insulating film portion, for electrically connecting to the P-type diffusion region and the N-type diffusion region of the first photodiode, and third and fourth electrodes are provided on the second insulating film portion, for electrically connecting to the P-type diffusion region and the N-type diffusion region of the second photodiode. Consequently, even though the first and the second photodiodes are of the same configuration as each other, by utilizing the change in transmissivity to light due to the discrepancy in the film thicknesses of the first film thickness of the first insulating film portion and the second film thickness of the second insulating film portion, the spectral sensitivity characteristics of the photoelectric currents detected from the first and second photodiodes can be made to have different characteristics from each other, and by arithmetic processing an illumination intensity sensor can be obtained having a peak sensitivity in the visible light region.

In addition, by utilizing the insulating properties of the first and second insulating film portions that are functioning as filters, it becomes possible to form each of the electrodes, for connecting the respective P-type diffusion regions and the respective N-type diffusion regions of the first and second photodiodes, directly on the first and second insulating film portions on the first and second photodiodes, so that a reduction in the surface area of the light receiving element when seen in plan view from above, thinning of the thickness of the light receiving element, and more compactness of the illumination intensity sensor can be achieved.

It should be noted that in the present exemplary embodiment explanation has been given of a P-type impurity for the first conduction type impurity and an N-type impurity for the second conduction type impurity, however a light receiving element may be configured in the opposite manner thereto, with an N-type impurity for the first conduction type impurity and a P-type impurity for the second conduction type impurity.

What is claimed is:

1. An illumination intensity sensor comprising:
a first photodiode comprising
a semiconductor substrate diffused with a first conduction type impurity,
a well region, formed on a front surface of the semiconductor substrate with a dispersed second conduction type impurity of opposite conductive type to that of the first conduction type impurity, and, disposed alongside each other on the front side in the well region,
a first conduction type diffusion region formed by diffusion of the first conduction type impurity and
a second conduction type diffusion region formed by diffusion of the second conduction type impurity;
a second photodiode disposed alongside the first photodiode and with the same configuration as the first photodiode;
an insulating film with transparency and insulating properties formed on the front surface of the first photodiode and on the front surface of the second photodiode, the insulating film including a first insulating film portion above the first photodiode of a first film thickness and a second insulating film portion above the second photodiode of a second film thickness that is thicker than the first film thickness;
a first electrode penetrating the first insulating film portion and electrically connected to the first conduction type diffusion region of the first photodiode;
a second electrode penetrating the first insulating film portion and electrically connected to the second conduction type diffusion region of the first photodiode;
a third electrode penetrating the second insulating film portion and electrically connected to the first conduction type diffusion region of the second photodiode: and
a fourth electrode penetrating the second insulating film portion and electrically connected to the second conduction type diffusion region of the second photodiode.

2. The illumination intensity sensor of claim 1, wherein the first film thickness is a thickness in the range of from 300 nm to 350 nm, and the second film thickness is in the range of from 400 nm to 450 nm.

3. The illumination intensity sensor of claim 1, wherein spectral sensitivity characteristics with a peak sensitivity in the visible light region are obtained, from the photoelectric current detected from the first photodiode and the photoelectric current detected from the second photodiode, by arithmetic processing to cancel out the spectral sensitivity to an infrared light region.

4. The illumination intensity sensor of claim 2, wherein spectral sensitivity characteristics with a peak sensitivity in the visible light region are obtained, from the photoelectric current detected from the first photodiode and the photoelectric current detected from the second photodiode, by arithmetic processing to cancel out the spectral sensitivity to an infrared light region.
